(19) United States
(12) Patent Application Publication
(10) Pub. No.: US 2025/0350261 A1
(43) Pub. Date: Nov. 13, 2025

(54) MITIGATION OF MALICIOUS SONIC ATTACKS ON VOICE-BASED COMPUTING DEVICES

(71) Applicant: Rowan University, Glassboro, NJ (US)

(72) Inventors: Chen SHEN, Mount Laurel, NJ (US); Joshua LLOYD, Pittsgrove, NJ (US)

(21) Appl. No.: 19/278,238

(22) Filed: Jul. 23, 2025

Related U.S. Application Data
(63) Continuation of application No. PCT/US2023/023459, filed on May 25, 2023.
(60) Provisional application No. 63/440,717, filed on Jan. 24, 2023.
(60) Provisional application No. 63/452,296, filed on Mar. 15, 2023.

(51) Int. Cl. H03H 9/46; G10L 17/26

(52) U.S. Cl. CPC H03H 9/46; G10L 17/26

(57) ABSTRACT

An acoustic filter mitigates audio signal-based attacks (particularly inaudible attacks in the ultrasonic frequency range) on voice-based computing devices by modulating the signals before they reach the device's microphone. One filter is formed as a rigid body defining multiple holes that exhibit local resonance phenomena that suppress incoming audio waves at specific frequencies. The filter distorts or otherwise modifies the attack signals and thereby prevents the microphone(s) from receiving the intended attack signal, and prevents the associated computing device from processing and executing the intended malicious “command”/signal. The filter can be tuned to be operable outside the frequency range of normal spoken commands, so that typical voice-based commands are unaffected by the filter. A frame is provided to enable one or more filters to be retrofitted to existing consumer electronics devices, outside their housings. Alternatively, new consumer electronics may be manufactured to include such filters inside their housings.

### CROSS-REFERENCE TO RELATED APPLICATIONS

This application is a continuation of International Application No. PCT/US23/23459, filed May 25, 2023, which claims the benefit of priority, under 35 U.S.C. § 119(e), of U.S. provisional patent application no. 63/440,717, filed Jan. 24, 2023, and 63/452,296, filed Mar. 15, 2023, the entire disclosure of each of which is hereby incorporated herein by reference.

### STATEMENT OF GOVERNMENT INTEREST

This invention was made with government support under Grant No. CMMI-2137749 awarded by the National Science Foundation. The government has certain rights in the invention.

### FIELD OF THE INVENTION

The present invention relates generally to computing devices having voice-based user interfaces, and more particularly, to a device with the ability to mitigate malicious sonic attacks, such as attacks using inaudible signals in the ultrasonic frequency range, on voice-based computing devices.

### DISCUSSION OF RELATED ART

An increasing number of computing devices include voice-based user interfaces. A characteristic of such voice-based computing devices is that they include a microphone for receiving/capturing ambient sound as an audio signal, and then performing a function as a result of such microphone-captured audio signal. Examples of such voice-based computing devices are smartphones, certain television remote control handsets, and so-called voice assistants, such as those commercially available as an Amazon Alexa, Apple Siri, Google Assistant, and Samsung Bixby-enabled computing devices.

For example, voice assistants like Amazon Alexa have the ability to control locks on doors and garages, alarm systems, and other electronics in someone's home. In addition, these voice assistants can have access to one's personal information including address, contacts, and payment information. All these variables pose a potential threat if the voice assistant was ever exploited to give another person access to these features. It poses a danger to an individual's home security and more broadly, the cybersecurity for internet-of-things.

Voice assistants, like other voice-based computing devices, play an important role in facilitating human-machine interactions and have been widely used in audio consumer electronic products. However, it has been shown that they are susceptible to inaudible attacks in which the malicious signals are not discernible by human ears. Accordingly, it is possible, for example, to perform a malicious attack on a voice-based computing device by using an inaudible audio signal as input to such a voice-based computing device to make the device perform an undesired/malicious function, without the awareness of the human user of the device, which is undesirable.

One way of accomplishing the exploitation of voice assistants is by using ultrasonic commands. These commands are outside of the audible range of humans; however, the microphones of these devices can still pick up the commands and execute them. This is because most microphones have an internal low-pass filter built into their hardware, with the cutoff usually being set at 20 kHz to allow devices to operate in the audible frequency range. However, due to a “shadow” effect that occurs on the microphone diaphragm, inaudible frequencies are able to be processed as regular message signals, making any smart assistant vulnerable to inaudible attacks.

While these ultrasonic attack signals can be defended against in a few ways, there does not exist a cost-effective solution that is efficient and robust in different conditions. For example, modifying the configuration of the hardware to include additional filters and circuits could potentially eliminate the shadow effect. This, however, requires additional components to the hardware and is complicated as the microphones are typically standardized. This drawback also applies to active noise control which allows selective filtering of ultrasonic frequencies but would be very costly and intrusive to realize. Modifying the software, on the other hand, does not provide a permanent solution as the attack signals could also be modified to work through the new software defenses.

What is needed is a device that can thwart or otherwise mitigate such inaudible attacks on voice-based computing devices. The present invention fulfills these needs, among others.

### SUMMARY

The present invention provides an acoustic filter configured to mitigate attacks (particularly inaudible attacks, e.g., in the ultrasonic frequency range) on voice-based computing devices by modulating the received signals before they reach the microphone of a voice-based computing device. The filter is based on the concept of metamaterials, which are engineered structures with embedded scatters, which are structures that can scatter incoming acoustic waves, e.g., by reflection, refraction, or scattering, that display certain properties. The filter is composed of rigid plates with individual holes that are configured to exhibit local resonance phenomena that suppress incoming waves at specific (e.g., inaudible) frequencies. By providing a filter with a suitable combination of holes, the filter can collectively distort the attack signals and thereby prevent the microphones from receiving the intended attack signal, and prevent the associated computing device from processing and executing the intended attack signal to protect the voice-based computing device from receiving the intended malicious “command”/signal. Additionally, normal audible signals (e.g., spoken commands) can be unaffected by the filter, as it may be configured to work mainly in the ultrasound spectrum (outside of the frequency range of spoken commands), which adds to the flexibility of the device. The metamaterial filter has a small footprint and can be easily installed in or on various audio-based consumer electronics products. The filters thereby improve the security of devices that use voice-based user interfaces.

### BRIEF DESCRIPTION OF THE FIGURES

An understanding of the following description will be facilitated by reference to the attached drawings, in which:

FIG. 1 is a perspective view of an exemplary acoustic filter in accordance with an exemplary embodiment of the present invention;

FIG. 2 is a top view of an exemplary acoustic filter in accordance with an exemplary embodiment of the present invention;

FIG. 3 is a bottom view of the exemplary acoustic filter of FIG. 2;

FIG. 4 is a front perspective view of an exemplary acoustic filter of FIG. 2;

FIG. 5 is a side perspective view of an exemplary acoustic filter of FIG. 2;

FIG. 6 is a perspective view of the exemplary voice-based computing device of the prior art;

FIG. 7 is a top view of a frame and acoustic filters of FIG. 2 fitted to the voice-based computing device of FIG. 6 in an axial orientation;

FIG. 8 is a top view of a frame and acoustic filters of FIG. 2 fitted to the voice-based computing device of FIG. 6 in a transverse orientation;

FIG. 9 is a perspective view of an exemplary voice-based computing device including an acoustic filter in accordance with the present invention;

FIG. 10 is an exemplary graph of received signal amplitude as a function of frequency, showing operability of the filter to attenuate undesirable frequencies; and

FIG. 11 is an exemplary graph of showing a net difference in received signal amplitudes as a function of frequency for the two cases shown in FIG. 10.

### DETAILED DESCRIPTION

The present invention provides an acoustic filter configured to mitigate audio-signal attacks by modulating the received signals before they reach the microphone of a voice-based computing device.

The inventive filter is preferably constructed based on the concept of metamaterials, and is composed of a rigid body defining individual openings that are configured (e.g., shaped and/or dimensioned) to act as resonance chambers to exhibit local resonance phenomena that suppress incoming waves in specific (e.g., ultrasonic and/or inaudible) frequency ranges. By providing a filter with a suitable combination of openings, the filter can collectively distort the attack signals and thereby protect the voice-based computing device from receiving the intended malicious “command”/signal. Additionally, the filter can be configured such that normal audible signals (e.g., spoken commands) are not affected by the filter, which adds to the flexibility of the device. The metamaterial filter has a small footprint and can be easily installed on various audio products. The filters thereby improve the security of devices that use voice-based user interfaces.

More particularly, a composite acoustic metamaterial filter is provided that is composed of a rigid body and individual resonators that are designed to work together to physically modify the attack signals (e.g., ultrasonic signal) so that it cannot trigger the intended action on the voice-based computing device. The proposed filters do not require any additional hardware to help prevent attack signals. They are small and can be conveniently installed on any voice assistant or other voice-based computing device. They are small and can be conveniently installed in or on any voice assistant or other voice-based computing device. In certain embodiments, when the filters are installed, inaudible (e.g., ultrasonic) and other frequency range attacks can be effectively mitigated while normal audible signals can still be processed without any interruptions. Due to the relatively simple configuration, these filters can be reliably fabricated by conventional manufacturing approaches or additive manufacturing and can be produced with reduced cost for mass production. In comparison to other defense methods, the metamaterial filters provide a much simpler and more cost-efficient option. More particularly, rather than requiring modification of voice-based assistant hardware or software, the inventive filters provide a reliable, mechanical solution to an electrical problem. Accordingly, the inventive filter provides a versatile solution for sound filtering in voice-based devices and greatly reduces the risk of smart speakers/voice assistants and/or other voice-based computing devices from being exploited by ultrasonic or other malicious commands.

Voice-based computing devices are subject to receiving signals outside of the audible spectrum that they are typically optimized for (e.g., 20 Hz-20 kHz) because of a so-called “shadow” effect of the microphones of these devices, which results in these devices picking up a specially modulated ultrasound signal containing information that can be further processed by them. This poses risks to the voice-based computing device as the ultrasound signals fall outside of the audible spectrum and are inaudible to humans, especially when malicious commands are attempted to be provided to the device.

The present invention provides a carefully designed filter based on acoustic metamaterials that can mitigate these attacks by filtering out the components outside the audible spectrum (e.g., in the ultrasonic spectrum) while having minimum disruption to signals within the audible frequency spectrum.

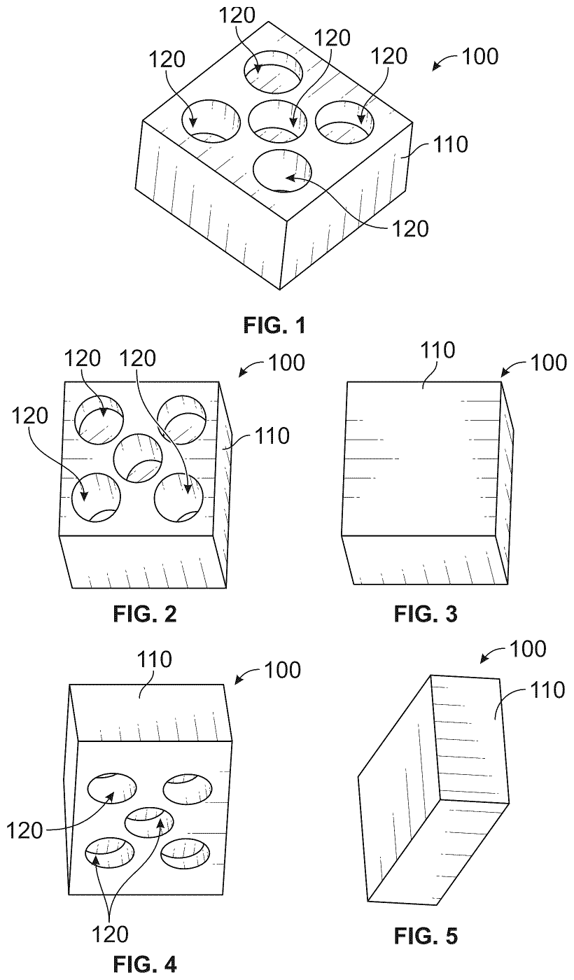

Referring now to FIGS. 1-5, an exemplary acoustic filter 100 in accordance with the present invention is shown. In accordance with the present invention, the acoustic filter 100 is constructed of a metamaterial that is designed to control, direct, and manipulate sound waves by modulating acoustic waves within specific frequencies, by rejecting (i.e., reflecting) more than absorbing such specific frequencies, e.g., frequencies in the ultrasonic frequency range. The acoustic filter includes a filter body 110 that has a base 112 sized to fit over the casing of the smart speaker and cover the microphone array in its entirety, and to provide the structures (e.g., openings) that provide the acoustic wave rejecting/filtering effect.

Notably, the filter body 110 is formed as a rigid body defining a plurality of open resonant chambers 120 configured to act as Helmholtz-like resonators. In the example shown, all open chambers have the same shape (in this case round in cross-section), the same cross-section dimensions (radii), and they are oriented with their axes in parallel orientations, and they are evenly spaced. However, any suitable combination of such parameters may be used for the openings to provide the desired filtering performance characteristics, as will be appreciated by those skilled in the art.

In the exemplary embodiment shown, the filter body 110 has external of dimensions 9.8 mm by 9.8 mm by 5.0 mm. Further, each open resonance chamber 120 has a radius of 1.5 mm and depths ranging from h₁ through h₅. The resonance frequency of these open resonance chambers 120 can be conveniently tuned by varying the depth of the holes to provide the desired filtering characteristics. Each opening may the same depth, or different openings may have different depths. The center frequency at which the filtering occurs is mainly related to the depths of the openings. A larger depth will shift the center frequency to lower frequencies while a smaller depth will increase the center frequency. Meanwhile, the factor which determines the working bandwidth around the center frequencies of the resonators mainly depends on their radii. Because each open resonance chamber has a certain bandwidth and only reduces a particular frequency, multiple open resonator chambers adapted to filter multiple different frequency ranges may be included to form a composite filter to increase the effective frequency band filtering within the ultrasonic frequency spectrum.

In the example shown, there are five individual open resonance chambers with dissimilar depths ranging from 1.0 mm to 3.0 mm are arranged on the filter body 110 to collectively provide an acceptable (exemplary) filtering effect. Such a configuration can effectively filter out incoming acoustic waves within specific frequencies.

The resonators can be varied in multiple ways, such as a combination of modifying the radius and depth of the openings, to provide certain filtering effects, e.g., narrow-band and strong filtering effect around several center frequencies or broadband and moderate filtering effect that covers a wider bandwidth. Specifically, the depth of the openings mainly controls the center frequency, and the radius of the openings mainly controls the filtering bandwidth. More particularly, the operating bands of the filter can be tuned by modifying the dimensions and configuration of the resonators, which could further lead to selective filtering within desired frequency bands. For example, one can tailor the center frequency and bandwidth of the filter by modifying the depth and radius of the corresponding holes. Moreover, the proposed structure can also be integrated with tunable components such as a screw-and-nut mechanism or a fluid injection module for reconfigurable filtering effects. These variables may be varied as desired to provide the desired filtering characteristics, as will be appreciated by those skilled in the art.

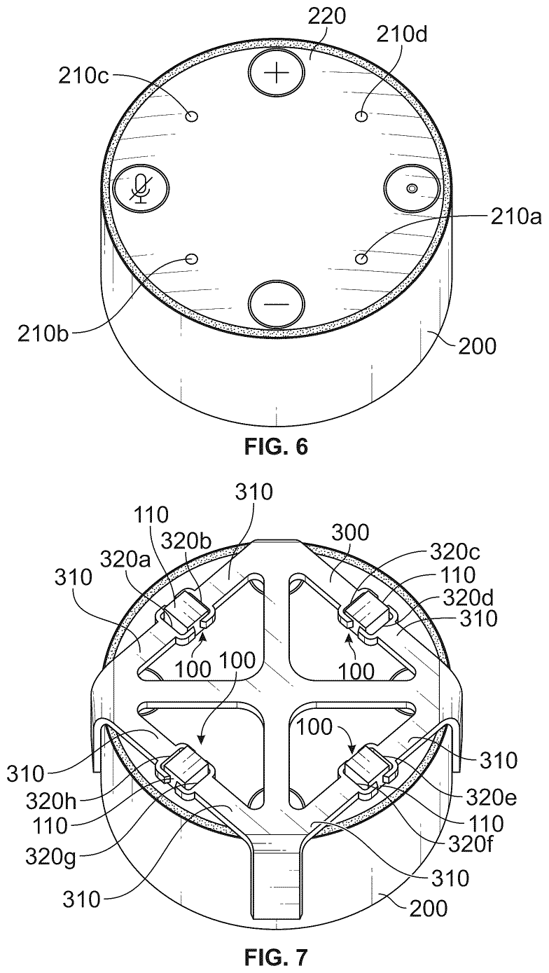

FIG. 6 is a perspective view of an exemplary voice-based computing device 200 of the prior art, namely, an Amazon Echo Dot, which uses the Amazon Alexa voice-based user interface. As known in the prior art, the device 200 includes four separate microphones 210a, 210b, 210c, 210d, e.g., to locate the direction of the signals as well as to suppress background noise. In a preferred embodiment, the number of metamaterial acoustic filters 100 should match the number of microphones 210 of the voice-based computing device, so that each microphone is protected by an associated filter.

FIG. 7 is a top view of an exemplary frame 300 suitable for use with the Amazon Echo Dot. More particularly, the exemplary frame 300 is shaped and dimension to fit on/over the Amazon Echo Dot 200, and includes supports 310 that include eight pairs of jaws 320a, 320b, 320c, 320d, 320e, 320f, 320g, 320h configured to support acoustic filters 100 in operative positions adjacent the microphones 210 of the Amazon Echo Dot 200. Accordingly, this particular frame 300 is customized for the Amazon Echo Dot. It should be appreciated that other frames may be constructed in customized fashion for other devices having different sizes/shapes, different numbers of microphones and/or different locations of microphones.

In this exemplary embodiment, adjacent pairs of jaws (e.g., 320a and 320b) are dimensioned and spaced to retain a filter 100 in a horizontal orientation therebetween, in a friction fit. In this embodiment, the axis of elongation of each open resonance chamber 210 extends in a direction (e.g., vertically) that is parallel to an axis of a respective microphone 210 (e.g., vertically), as will be appreciated from FIG. 7. Accordingly, in the example of FIG. 7, the frame 300 is being used to support four acoustic filters 100 in an axially-aligned orientation. This orientation may be preferably in certain applications.

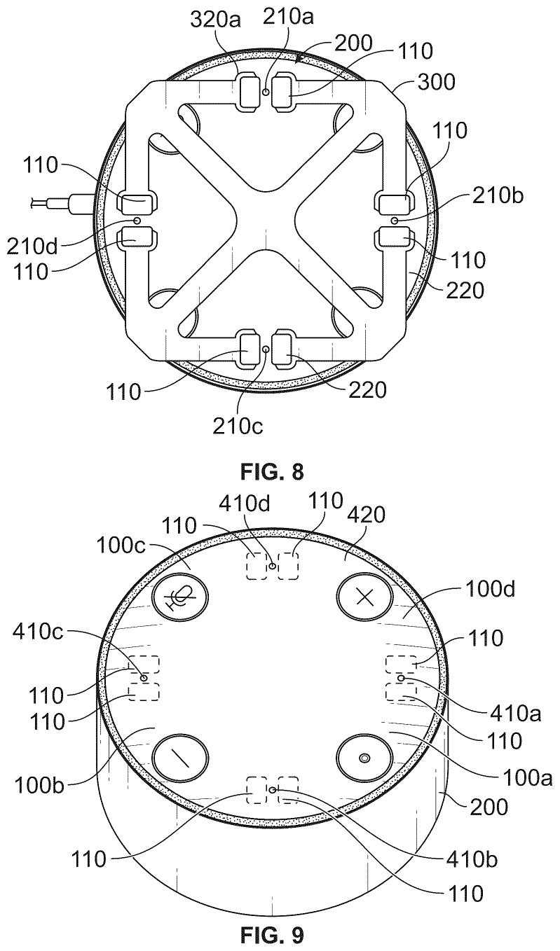

In this exemplary embodiment, each pair of jaws (e.g., 320a) is dimensioned and spaced to retain a filter 100 in an upright orientation therebetween in a friction fit. In this embodiment, the axis of elongation of each open resonance chamber 210 extends in a direction (e.g., horizontally) that is transverse to an axis of a respective microphone 210 (e.g., vertically), as will be appreciated from FIG. 8. Accordingly, in the example of FIG. 8, the frame 300 is being used to support eight acoustic filters 100 in a transverse orientation.

Accordingly, the frame 300 may be used to retrofit acoustic filters 100 to an existing voice-based computing device, after manufacture of the voice-based computing device. In such a scenario, the acoustic filters 100 are located externally to the housing 220 of the of the voice-based computing device 200.

Alternatively, voice-based computing devices may be manufactured to include one or more acoustic filters 100 in accordance with the present invention. In such an embodiment, the acoustic filters 200 may be similarly positioned adjacent to or aligned with microphones of the device, but in this case, the acoustic filter(s) may be located internally to the housing 420 of the voice-based computing device 400. FIG. 9 shows an exemplary voice-based computing device 400 in accordance with the present invention that includes one or more acoustic filters 100 in accordance with the present invention positioned internally to the housing 420, in positions adjacent to/aligned with its microphones 410a, 410b, 410c, 410d. Accordingly, as illustrated schematically in FIG. 9, when a metamaterial filter 100 is installed, malicious commands (e.g., inaudible signals) in the filtered frequency range (e.g., ultrasonic frequency range) are filtered by the filters and effectively blocked so that they will not trigger the voice assistants to perform the intended malicious function(s).

### EXAMPLE

A malicious attack may be delivered to a voice-based assistant based on the so-called “shadow effect.” The shadow effect concept is most easily understood by using two single tones. These two tones will generate frequencies that are equal to the sum and difference of the two tones when they vibrate the microphone. For example, if two sine waves at 40 kHz and 50 kHz are played, they will yield frequencies at 10 kHz and 90 kHz at the microphone. The 90 kHz signal is still outside of the microphone's audible range, however, the 10 kHz is right in the middle of it, so the microphone will pick up the 10 kHz frequency. If amplitude modulation is further utilized with a message signal of 8 kHz and lower, a signal with a bandwidth of 16 kHz can be created. This yields frequencies in the audible range of 20 Hz to 16 kHz, which completely falls into the operating band of the microphone. Therefore, by utilizing amplitude modulation, a message signal which acts as the original command can be shifted into the ultrasonic range and can then be demodulated and interpreted by the microphone.

Ultrasonic attack signals were created and delivered to a third-generation Amazon Echo Dot-type voice-based computing device. The ultrasound signals were obtained by modulating the regular voice commands and shifting them into the inaudible range to exploit the shadow effect. Namely, a high-pass filter was applied to the original audible audio file to eliminate unnecessary high-frequency components and then up-sample the file to 192 kHz. Next, the audio was modulated into the ultrasonic frequency range and manipulated to take advantage of the shadow effect. Due to the need for a very high sample rate, a Focusrite Scarlett Solo audio interface was used as the digital-to-analog converter (DAC). A dedicated high-resolution DAC, separate from the host computer was used in sending the attack signal. This signal was sent to a Yamaha R-S202 for amplification to increase the effective range of the attack signal, and then to a Fostex FT17H ultrasonic speaker. The attack signal was played from the ultrasonic speaker and received by the voice-based computing device or various testing.

Testing criteria included multiple voice-based computing device orientations, angles, and distances from the ultrasonic speaker. The voice-based computing device was tested both vertically (facing the ultrasonic speaker) and horizontally (lying flat on the table). Each of these orientations was also tested at an angle of 4 degrees and 8 degrees offset from the direct center of the ultrasonic speaker's throw. The distance between the smart speaker and ultrasonic speaker ranged from 0.3 m to 1.83 m, with each test increasing the distance by 0.31 m. Three trials were run at each distance, angle, and orientation, both with and without the filters placed on the voice-based computing device.

When the voice-based computing device was in a vertical orientation, without filtering, the malicious ultrasonic audio command was successful in triggering the intended action 100% of the time. At each distance, angle, and orientation the voice-based computing device was successfully triggered by the ultrasonic attack signal. When the filters were added, the voice-based computing device was never triggered by the attack signal, which results in a 100% success rate.

For the horizontal orientation, without the filtering, the voice-based computing device was able to be triggered 0.3 m away between zero and four degrees, and at 0.61 m between zero and four degrees. At these locations, the voice-based computing device was triggered 100% of the time by the attack signal. The triggering rate dropped at larger angles and longer distances, which was caused by the high directivity of ultrasonic signals and the quick attenuation of acoustic energy at higher frequencies. When the filters were applied, the voice-based computing device was not triggered during any test in the horizontal orientation. On the other hand, normal voice commands were not affected as the metamaterial filters were configured to operate mainly in the ultrasound regime, and the voice-based computing device responded in all of the configurations.

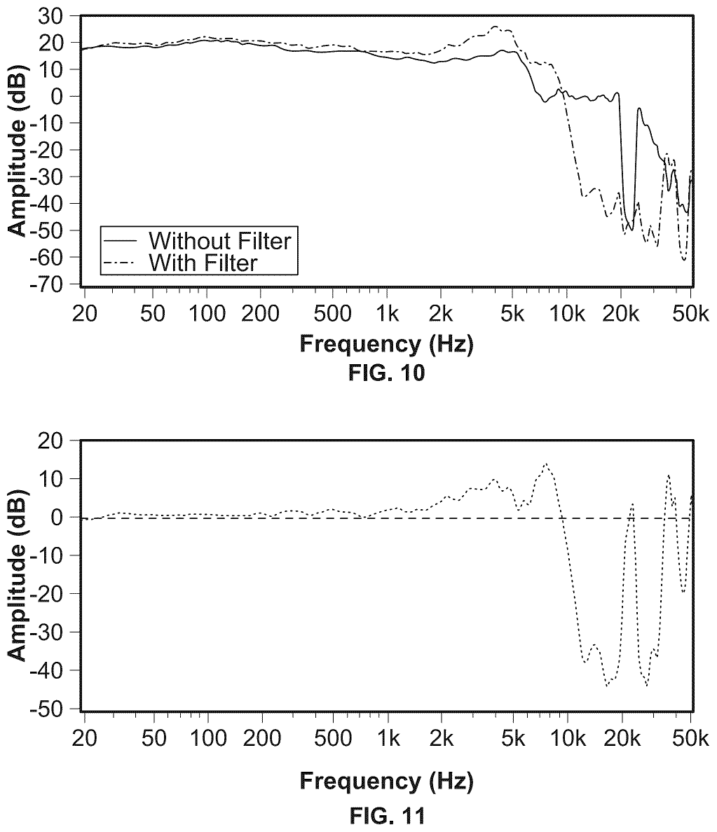

To further characterize the filtering performance of the metamaterial, the received signal from the microphone was recorded to obtain its frequency spectrum. Pink noise was played 30 cm away from the microphone to include both audible and ultrasonic frequencies. This pink noise was then recorded both with and without a filter present. The results are summarized in FIGS. 10a and 10b. FIG. 10a shows the frequency response of the microphone without and with a filter. FIG. 10b shows the difference between each frequency response, indicated by the yellow (With Filter) overlay. As shown, the filtering effect took place mostly within the ultrasonic frequencies and did not much affect the audible components. Due to this selective filtering effect, the metamaterial filters effectively mitigated ultrasound attacks and presented negligible impact on regular voice commands.

FIG. 10 is an exemplary graph of received signal amplitude as a function of frequency, showing operability of the filter to attenuate undesirable frequencies. FIG. 11 is an exemplary graph of showing a net difference in received signal amplitudes as a function of frequency for the two cases shown in FIG. 10. As will be appreciated from FIGS. 10 and 11, the associated exemplary filter is structured and effective to filter (and cause associated signal reduction) mainly within the ultrasonic frequency range (to filter out inaudible malicious commands in the ultrasonic frequency range) while leaving the audible frequency range (e.g., 20 Hz-20 kHz) largely unaffected by the filter, to allow for legitimate user-spoken commands within the audible frequency range to be received and suitable processed as intended by the voice-based computing device.

While there have been described herein the principles of the invention, it is to be understood by those skilled in the art that this description is made only by way of example and not as a limitation to the scope of the invention. Accordingly, it is intended by the appended claims, to cover all modifications of the invention which fall within the true spirit and scope of the invention.

What is claimed is:

1. An acoustic filter configured to mitigate audio-signal attacks in a frequency range, the acoustic filter comprising:
a filter body having an outer surface; and
at least one resonant chamber defined by said filter body and open to said outer surface, said at least one resonant chamber being configured to resonate in response to an incident acoustic signal to suppress energy of said signal in at least one frequency band within the frequency range.

2. The acoustic filter of claim 1, wherein said filter body is constructed of a rigid material.

3. The acoustic filter of claim 1, wherein said filter body is constructed of an acoustic metamaterial.

4. The acoustic filter of claim 1, wherein said acoustic filter comprises a plurality of resonant chambers open to said outer surface, each of said plurality of resonant chambers being configured to resonate in response to energy.

5. The acoustic filter of claim 1, wherein said plurality of resonant chambers differ in at least one of respective volumes, respective shapes, respective cross-sectional areas, and respective depths.

6. The acoustic filter of claim 1, wherein each of said plurality of resonant chambers differs in resonant characteristics from others of said plurality of resonant chambers.

7. The acoustic filter of claim 1, wherein said at least one resonant chamber suppresses energy of said signal in at least one frequency band within an ultrasonic frequency range.

8. The acoustic filter of claim 1, wherein said at least one resonant chamber does not suppress energy of said signal in an audible frequency range of 20 Hz to 20 kHz.

9. The acoustic filter of claim 1, wherein said at least one resonant chamber suppresses energy of said signal in at least one frequency band within an audible frequency range.

10. The acoustic filter of claim 1, wherein said at least one resonant chamber distorts said signal in at least one frequency with said frequency range.

11. An acoustic filter configured to mitigate audio-signal attacks in a frequency range, the acoustic filter comprising:
a filter body;
at least one energy scattering structure that disrupts an incident acoustic signal by modulating acoustic waves of said signal in at least one frequency band within the frequency range.

12. The acoustic filter of claim 11, wherein each of said at least one energy scattering structure comprises a respective resonant chamber configured to resonate in response to the incident acoustic signal.

13. An acoustic filter system configured to mitigate audio-signal attacks in a frequency range on a voice-based computing device comprising at least one microphone and capable of processing input received via said at least one microphone, the acoustic filter system comprising:
at least one acoustic filter disposed in a position to be positionable adjacent each of microphone of said voice-based computing device, each of said at least one acoustic filter comprising:
a filter body having an outer surface; and
at least one resonant chamber defined by said filter body and open to said outer surface, said at least one resonant chamber being configured to resonate in response to an incident acoustic signal to suppress energy of said signal in at least one frequency band within the frequency range.

14. The acoustic filter system of claim 13, further comprising:
a frame shaped and dimensioned to support said at least one acoustic filter in said position.

15. The acoustic filter system of claim 14 wherein said frame is shaped and dimensioned to support said at least one account filter relative to a specific model of voice-based computing device.

16. The acoustic filter system of claim 13, further comprising:
a respective pair of jaws corresponding to each of said at least one acoustic filter, each of said pair of jaws being configured to support a respective acoustic filter in an operative position relative to a respective microphone.

17. The acoustic filter system of claim 16, wherein each of said pair of jaws is configured to support said respective acoustic filter in a transverse orientation relative to an axis of said respective microphone.

18. The acoustic filter system of claim 16, wherein each of said pair of jaws is configured to support said respective acoustic filter in a parallel orientation relative to an axis of said respective microphone.

19. The acoustic filter system of claim 13, wherein said acoustic filter system is configured to support said at least one acoustic filter in said position externally to a housing of said voice-based computing device.

20. The acoustic filter system of claim 13, wherein said acoustic filter system is configured to support said at least one acoustic filter in said position internally to a housing of said voice-based computing device.

21. A voice-based computing device capable of processing input received via a microphone and mitigating audio-signal attacks in a frequency range, the acoustic voice-based computing device comprising:
a microphone,
a processor operatively connected to the microphone for receiving an audio signal;
a memory operatively connected to the processor, said memory storing executable instructions that, when executed by the processor, causes the processor to process the audio signal and perform at least one instruction step associated with the audio signal; and
an acoustic filter configured to mitigate audio-signal attacks in a frequency range, said acoustic filter being disposed adjacent said microphone and comprising:
a filter body having an outer surface; and
at least one resonant chamber defined by said filter body and open to said outer surface, said at least one resonant chamber being configured to resonate in response to an incident acoustic signal to suppress energy of said signal in at least one frequency band within the frequency range.
